(19) United States
(12) Patent Application Publication
(10) Pub. No.: US 2007/0126454 A1
(43) Pub. Date: Jun. 7, 2007

(54) Apparatus and method of detecting defective substrate

(75) Inventor: Chun-ku Han, Seoul (KR)

Correspondence Address: STANZIONE & KIM, LLP, 919 18TH STREET, N.W., SUITE 440, WASHINGTON, DC, 20006, US

(73) Assignee: Samsung Elecronics Co., Ltd., Suwon-si (KR)

(21) Appl. No.: 11/583,837

(22) Filed: Oct. 20, 2006

(30) Foreign Application Priority Data
Nov. 30, 2005 (KR) 2005-115842

(51) Int. Cl. G01R 31/26

(52) U.S. Cl. 324/765

(57) ABSTRACT

An apparatus and method of detecting a functionally defective substrate includes a detection unit to detect a trend in change in a voltage of a power source when a substrate is heated by the power source given by discharging of a capacitor and a test unit to compare the detected trend to a trend of change set in advance and to output the comparison result as a determination signal which indicates whether the substrate has a defect.

### CROSS-REFERENCE TO RELATED APPLICATIONS

This application claims priority under 35 U.S.C. §119 (a) from Korean Patent Application No. 10-2005-0115842, filed on Nov. 30, 2005, in the Korean Intellectual Property Office, the disclosure of which is incorporated herein in its entirety by reference.

### BACKGROUND OF THE INVENTION

1. Field of the Invention

The present general inventive concept relates to an image forming apparatus, and more particularly, to an apparatus and a method of determining whether a substrate has a functional defect by sensing a trend of change in a voltage of a power source when the substrate is heated using the power source and by comparing the sensed trend to a predetermined trend of change.

2. Description of the Related Art

In a thermal type inkjet printer, a substrate on which a nozzle is disposed is heated to generate air bubbles on a surface of an ink, and the generated air bubbles make the ink discharge through the nozzle to form an image on a printing medium.

Accordingly, to form an image without any defect, the substrate should be heated to a required temperature within a predetermined time. If the substrate has a functional defect, heating of the substrate cannot be performed appropriately, so that forming of the image without any defect cannot be accomplished.

However, functional defects of substrates are inevitable in a mass production process, and a functional defect may appear later in a substrate manufactured without any defect.

Functionally defective substrates should be detected as soon as possible. To detect a defective substrate, a manufactured substrate is tested before the substrate is employed in an inkjet printer, or a substrate already installed in an inkjet printer is tested using a defect test unit included in the inkjet printer.

Accordingly, costs required to test the substrate increase a manufacturing cost of the inkjet printer, thereby decreasing market competitiveness of an inkjet printer manufacturer. Thus, an inexpensive or efficient method of detecting a functionally defective substrate is desirable.

### SUMMARY OF THE INVENTION

The present general inventive concept provides an apparatus to detect a functionally defective substrate by detecting a trend of change in a voltage of a power source when a substrate is heated by the power source in response to a capacitor discharge and comparing the detected result to a predetermined trend of change that is set in advance.

The present general inventive concept also provides a method of detecting a functionally defective substrate by detecting a trend of change in a voltage of a power source when a substrate is heated by the power source in response to a capacitor discharge and comparing the detected result to a predetermined trend of change that is set in advance.

Additional aspects and advantages of the present general inventive concept will be set forth in part in the description which follows and, in part, will be obvious from the description, or may be learned by practice of the general inventive concept.

The foregoing and/or other aspects of the present general inventive concept may be achieved by providing an apparatus to detect a functionally defective substrate, the apparatus including a detection unit to detect a trend in change in a voltage of a power source when a substrate is heated by the power source given by discharging of a capacitor, and a test unit to compare the detected trend of the detection unit to a predetermined trend of change and to output the comparison result as a determination signal which indicates whether the substrate has a defect. Here, the substrate may be one of a plurality of substrates formed in a single body

The apparatus may further include a calculation unit to calculate a difference between voltages detected at first and second time points, the test unit compares the calculated difference to a predetermined critical value and outputs the comparison result as the determination signal, and the first and second time points exist in a heating period.

The foregoing and/or other aspects of the present general inventive concept may be achieved by providing a method of detecting a functionally defective substrate, the method including detecting a trend of change in a voltage of a power source while a substrate is heated by the power source given by discharging of a capacitor, determining whether the detected trend of change in the voltage of the power source is the same as a trend of change set in advance, and determining the substrate to be a functionally defective substrate if the detected trend of change in the voltage of the power source is the same as the trend of change set in advance.

The foregoing and/or other aspects of the present general inventive concept may be achieved by providing a computer readable record medium having embodied thereon a computer program to execute a method of detecting a functionally defective substrate, the method including detecting a trend of change in a voltage of a power source while a substrate is heated by the power source given by discharging of a capacitor, determining whether the detected trend of change in the voltage of the power source is the same as a trend of change set in advance, and determining the substrate to be a functionally defective substrate if the detected trend of change in the voltage of the power source is the same as the trend of change set in advance.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram illustrating an apparatus to detect a functionally defective substrate according to an embodiment of the present general inventive concept;

FIG. 2 is a view illustrating an exemplary timing chart of a voltage detected by a detection unit of the apparatus of FIG. 1; and

FIG. 3 is a flowchart illustrating a method of detecting a functionally defective substrate according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

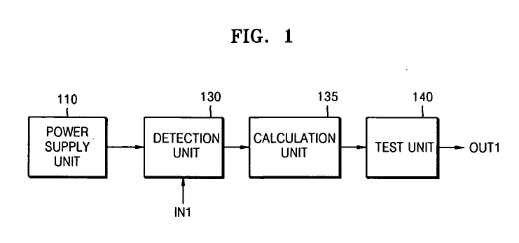

FIG. 1 is a block diagram illustrating an apparatus to detect a functionally defective substrate according to an embodiment of the present general inventive concept. The apparatus to detect the functionally defective substrate includes a power supply unit 110, a detection unit 130, a calculation unit 135, and a test unit 140.

The power supply unit 110, the detection unit 130, the calculation unit 135, and test unit 140 may be included in an image forming apparatuses such as a printer and a multi-function peripheral (MFP). The image forming apparatus may be a thermal type inkjet printer.

The image forming apparatus includes a print head having head chips, and each head chip may include one or more substrates. However, hereinafter only one substrate is assumed to be included in a head chip for the convenience of description.

The image forming apparatus may be of a shuttle type or a line type. In a shuttle type image forming apparatus, only one head chip is included, and printing is performed during a reciprocating movement of the print head with respect to a printing medium. On the other hand, in a line type image forming apparatus, a plurality of head chips which are formed in a single body are included, and the reciprocating movement of the print head is not required to print an image on the printing medium. An example of the image forming apparatus of the line type includes a pulse width inkjet printer.

Hereinafter, for the convenience of description, the power supply unit 110, the detection unit 130, the calculation unit 135, and test unit 140 are assumed to be included in a line type image forming apparatus having N (N is an integer equal to or larger than two) head chips.

The power supply unit 110 supplies power to a substrate heating unit (not shown), and the substrate heating unit heats a substrate arranged in the head chip using the supplied power.

Operations of the head chip including heating of the substrate should be controlled precisely, so the precise control of the operations may be performed by a power source of which voltage can be controlled precisely. For the precise control of the voltage, a capacitor (not shown) may be included in the power supply unit 110. In this case, after the capacitor (not shown) is charged completely, the power supply unit 110 supplies power which is generated by discharging the charged capacitor.

As described above, the power supplied to a substrate heating unit (not shown) is provided in response to the discharge of the capacitor. In other words, the voltage of the power source supplied from the power supply unit 110 decreases as a discharge rate of the capacitor increases. Accordingly, the voltage of the power source supplied does not change rapidly and decreases gradually within a predictable range. Since the substrate heating unit having a substrate and a heater disposed in or on the substrate to heat the head chip disposed on the substrate, and the power supply unit 110 having the capacitor as the power source to supply the power to the heater and/or the substrate are well known, detailed descriptions and structures thereof will be omitted.

The detection unit 130 detects a pattern of change in the voltage of the power supplied from the power supply unit 110. More specifically, the detection unit 130 detects the pattern of the change in the voltage of the power source supplied to the substrate heating unit from the power supply unit 110.

The detection unit 130 operates in response to a detection signal input to an input terminal IN 1. The detection signal may be generated continuously when the substrate heating unit (not shown) receives the power or the detection indication signal is generated only while the substrate is heated.

When the substrate is heated, the voltage of the power supplied from the power supply unit 110 decreases more rapidly than a voltage decrease due to the increase in the discharge rate of the capacitor. At this time, if the substrate has a defect, the decrease in the voltage of the power source while the substrate is heated is the same as or similar to a voltage decrease according to the increase in the discharge rate of the capacitor.

Accordingly, the apparatus to detect a functionally defective substrate sets in advance a pattern of the change in the voltage of the source power which appears when the substrate has a defect, and determines the substrate to be a defective substrate when a detected pattern of the change in the voltage of the source power corresponds to the set pattern of the change of the voltage to detect a defective substrate. Here, the defect and/or the functionally defected substrate represents a defected state where a heating operation of heating a heater or a substrate to generate bubbles to eject ink through a nozzle is not properly performed due to a material composition defect in the substrate, an electrical connection defect between the print head and the power source, or a short-circuit thereof.

The apparatus to detect a functionally defective substrate according to an embodiment of the present general inventive concept may further include the calculation unit 135. In this case, the detection unit 130 detects voltages at first and second time points, respectively, and the calculation unit 135 calculates a difference between the detected voltages at the first and second time points. Here, the first and second time points are arbitrarily selected two time points within a period in which the substrate is heated, that is, a heating period. For example, the first time point may be a time point at which the substrate starts to be heated, and the second time point may be a time point at which heating of the substrate is completed.

The test unit 140 compares the detected pattern of change in the voltage detected by the detection unit 130 according to the calculated difference of the calculation unit 135 to the pattern of the change of the voltage set in advance, and outputs a determination signal indicating a defective substrate based on a result of the comparison. Here, the pattern of change of the voltage set in advance represents a predetermined pattern of the change of the voltage when the substrate has a defect, and the determination signal for the defective substrate is a signal indicating whether the substrate has a defect. The determination signal for the defective substrate is output from an output terminal OUT1.

More specifically, when the detected pattern of the change in the voltage detected by the detection unit 130 is determined to be the same as that of the change in the voltage set in advance by the detection unit 140, the detection unit 140 outputs the determination signal indicating the defective substrate.

When the detected pattern of change in the voltage detected by the detection unit 130 is determined to be not the same as or similar to the pattern of change in the voltage set in advance by, for example, the test unit 140, the test unit 140 outputs the determination signal indicating that the substrate has no defect.

In the same method described above, the detection unit 140 may compare the voltage difference calculated by the calculation unit 135 to a predetermined critical value and output the determination signal indicating the defective substrate based on a result of the comparison.

More specifically, when the test unit 140 determines that the voltage difference calculated by the calculation unit 135 is less than the critical value, the test unit 140 outputs a determination signal indicating that the substrate has a defect. The test unit 140 may generate the determination signal as a display signal to display an image to indicate that the substrate is a defective substrate, according to the determination of whether the substrate is the functionally defective substrate.

When the test unit 140 determines that the voltage difference calculated by the calculation unit 135 is equal to or larger than the critical value, the test unit 140 outputs the determination signal indicating that the substrate has no defect.

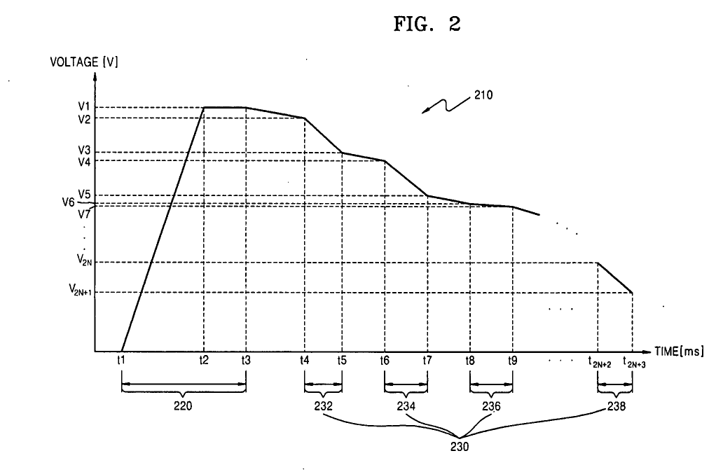

FIG. 2 is a view illustrating an exemplary timing chart 210 of the voltage detected by the detection unit 130 in the apparatus of FIG. 1. A capacitor (not shown) included in the power supply unit 110 is charged from a time t1 to a time t3. Reference number 220 indicates a period to change the capacitor.

As illustrated in FIG. 2, a voltage applied to the capacitor when the capacitor is fully charged at time t2 has a value V1.

The charging of the capacitor continues until time t3, however, after time t3, the capacitor is discharged and accordingly the voltage applied to the capacitor is decreased gradually.

As described above, the power supply unit 110, the detection unit 130, the calculation unit 135, and test unit 140 are assumed to be included in the image forming apparatus in which N head chips are formed in a single body. Here, a method of detecting a functionally defective substrate according to an embodiment of the present general inventive concept is executed for each of the N head chips or substrates.

Here, N may be an integer equal to or larger than four, and reference numbers 232, 234, 236, and 238 indicate periods 230 during which the substrates are heated, respectively. More specifically, a first substrate is heated from a time t4 to a time t5, a second substrate is heated from a time t6 to a time t7, a third substrate is heated from a time t8 to a time t9, and an N-th substrate is heated from a time t_{2N+2} to a time t₂ₙ₊₃.

FIG. 2 illustrates voltages detected by the detection unit 130 when the first, second, and N-th substrates have no defect, and another voltage detected by the detection unit 130 when the third substrate has a defect. The detected pattern of change in the voltage while the defected third substrate is heated, that is, the detected pattern of change in the voltage during a period from time t8 to time t9, is similar to a set pattern of decrease in the voltage of the discharging capacitor according to an increase of a discharge rate of the capacitor. However, detected patterns of changes during periods from time t3 to time t4, from time t5 to t6, and from time 7 to time 8, are different from the detected pattern of change during the period from time t8 to time t9 or are not the same as or similar to the set pattern of decrease in the voltage of the discharging capacitor according to the increase of the discharge rate of the capacitor.

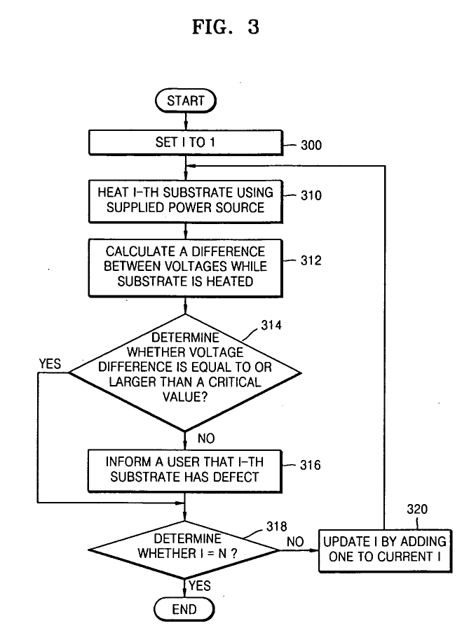

FIG. 3 is a flowchart illustrating a method of detecting a functionally defective substrate according to an embodiment of the present general inventive concept. The method includes operations 300, 310, and 320 in which a pattern of change in a power source is detected while a prepared substrate is heated by the power that is generated by a capacitor discharge, and the detected result is compared to a pattern of change set in advance to detect whether the substrate has a defect.

The image forming apparatus including the power supply unit 110, the detection unit 120, the calculation unit 130, and test unit 140 sets i to one (300). The substrate heating unit (not shown) heats an i-th substrate using power supplied from the power supply unit 110 (310). Here, the provided power may be generated by a capacitor discharge.

After operation 310, the detection unit 130 detects voltages of the supplied power at first and second time points, and the calculation unit 135 calculates a difference between the detected voltages at the first and second time points (312).

After operation 312, the detection unit 140 determines whether the difference between the voltages is less than a predetermined critical value (314).

After operation 314, when the difference between the voltages is determined to be less than the predetermined critical value, a display unit (not shown) displays a message informing a user that the i-th substrate is defective (316).

When the substrate is determined to be a functionally defective substrate after operation 316 or in operation 314, the test unit 140 determines whether i is equal to N (318), and if i is determined that i is not equal to N, the image forming apparatus updates i by adding one to the current i (320), and operation 310 is executed.

The present general inventive concept can also be embodied as computer-readable codes on a computer-readable recording medium to perform the above-described method of detecting a functionally defective substrate. The computer-readable recording medium is any data storage device that can store data which can be thereafter read by a computer system. Examples of the computer-readable recording media include read-only memory (ROM), random-access memory (RAM), CD-ROMs, magnetic tapes, floppy disks, optical data storage devices, and carrier waves (such as data transmission through the Internet). The computer-readable recording medium can also be distributed over network-coupled computer systems so that the computer-readable code is stored and executed in a distributed fashion. Also, functional programs, codes, and code segments to accomplish the present general inventive concept can be easily construed by programmers skilled in the art to which the present general inventive concept pertains.

As described above, according to the apparatus and method according to an embodiment of the present general inventive concept, an inkjet printer can detect a functionally defective substrate without using an additionally installed component, so that it is possible to detect a functionally defective substrate without increasing manufacturing costs of the inkjet printer.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An apparatus to detect a functionally defective substrate, comprising:
a detection unit to detect a trend in change in a voltage of a power source when a substrate is heated by the power source given by discharging of a capacitor; and
a test unit to compare the detected trend to a trend of change set in advance and to output the result of the comparison as a determination signal which indicates whether the substrate has a defect.

2. The apparatus of claim 1, wherein the substrate comprises one of a plurality of substrates formed in a single body.

3. The apparatus of claim 1, further comprising:
a calculation unit to calculate a difference between voltages detected at first and second time points,
wherein:
the test unit compares a result of the calculation to a predetermined critical value and outputs the result of the comparison as the determination signal, and
the first and second time points exist in a heating period.

4. The apparatus of claim 1, wherein the detection unit detects voltages during a heating period as the trend of the change, and the test unit compares the detected voltages with a reference and outputs the result of the comparison as the determination signal which indicates whether the substrate has the defect.

5. The apparatus of claim 1, wherein the detection unit detects voltages during a heating period as the trend of the change, and the test unit compares a difference between the detected voltages with a reference and outputs the result of the comparison as the determination signal which indicates whether the substrate has the defect.

6. The apparatus of claim 1, wherein the detection unit detects a voltage change rate during a heating period as the trend of the change, and the test unit compares a voltage change rate with a reference and outputs the result of the comparison as the determination signal which indicates whether the substrate has the defect.

7. The apparatus of claim 1, wherein:
the substrate comprises a first substrate and a second substrate formed in a single body;
the detection unit detects a first trend in change in the voltage of the power source during a first period when the first substrate is heated by the power source, and detects a second trend in change in the voltage of the power source during a second period when the second substrate is heated by the power source; and
the test unit compares the detected first trend to a first reference trend of change to output the result of the comparison as the determination signal which indicates whether the first substrate has the defect, and compares the detected second trend to a second reference trend of change to output the result of the comparison as the determination signal which indicates whether the second substrate has the defect.

8. The apparatus of claim 7, wherein the first reference trend and the second reference trend are the same.

9. The apparatus of claim 1, wherein the test unit outputs the determination signal as a display signal to display that the substrate has the defect.

10. A method of detecting a functionally defective substrate, the method comprising:
detecting a trend of change in a voltage of a power source while a substrate is heated by the power source given by discharging of a capacitor;
determining whether the detected trend of change in the voltage of the power source is the same as a trend of change set in advance; and
determining the substrate is a functionally defective substrate if the detected trend of change in the voltage of the power source is the same as a trend of change set in advance.

11. The method of claim 10, wherein the substrate is one of a plurality of substrates formed in a single body.

12. The method of claim 10, further comprising
calculating a difference between voltages detected at first and second time points,
wherein:
the determining of whether the detected trend of change in the voltage of the power source is the same as a trend of change set in advance comprises determining whether the calculated difference between the detected voltages is less than a predetermined critical value,
the determining of the substrate is the functionally defective substrate comprises determining the substrate is the functionally defective substrate if the calculated difference between the detected voltages is less than the predetermined critical value, and
the first and second time points exist in a heating period.

13. The method of claim 10, further comprising:
displaying that the substrate is a defective substrate, according to the determination of whether the substrate is the functionally defective substrate.

14. The method of claim 10, wherein:
the detecting of the trend of change comprises detecting voltages during a heating period as the trend of the change; and
the determining of whether the detected trend of change in the voltage of the power source is the same as the trend of change set in advance comprises determining the detected voltages is the same as a reference,
the determining of the substrate is the functionally defective substrate comprises determining the substrate is the functionally defective substrate if the detected voltages is the same as the reference.

15. The method of claim 10, wherein:
the detecting of the trend of change comprises detecting voltages during a heating period as the trend of the change; and
the determining of whether the detected trend of change in the voltage of the power source is the same as a trend of change set in advance comprises determining a difference between the detected voltages is the same as a reference
the determining of the substrate is the functionally defective substrate comprises determining the substrate is the functionally defective substrate if the difference between the detected voltages is the same as the reference

16. The method of claim 10, wherein:
the detecting of the trend of change comprises detecting a voltage change rate during a heating period as the trend of the change; and
the determining of whether the detected trend of change in the voltage of the power source is the same as a trend of change set in advance comprises determining the detected voltage change rate is the same as a reference,
the determining of the substrate is functionally defective substrate comprises determining the substrate is the functionally defective substrate if the detected voltage change rate is the same as the reference

17. A computer readable record medium having embodied thereon a computer program to execute a method of detecting a functionally defective substrate, the method comprising:
detecting a trend of change in a voltage of a power source while a substrate is heated by the power source given by discharging of a capacitor;
determining whether the detected trend of change in the voltage of the power source is the same as a trend of change set in advance; and
determining the substrate is a functionally defective substrate if the detected trend of change in the voltage of the power source is the same as the trend of change set in advance.

18. The computer readable recording medium of claim 17, wherein the substrate is one of a plurality of substrates formed in a single body.

19. The computer readable recording medium of claim 17, the method further comprising
calculating a difference between voltages detected at first and second time points,
wherein:
the determining of whether the detected trend of change in the voltage of the power source is the same as a trend of change set in advance comprises determining whether the calculated difference between the detected voltages is less than a predetermined critical value,
the determining of the substrate is the functionally defective substrate comprises determining the substrate is the functionally defective substrate if the calculated difference between the detected voltages is less than the predetermined critical value, and
the first and second time points exist in a heating period.

20. The computer readable recording medium of claim 17, the method further comprising:
displaying that the substrate is a defective substrate, according to the determination of whether the substrate is the functionally defective substrate.
